(19) United States
(12) Patent Application Publication
(10) Pub. No.: US 2013/0308276 A1
(43) Pub. Date: Nov. 21, 2013

(54) SEMICONDUCTOR DEVICE AND MANUFACTURING METHOD FOR SAME

(71) Applicant: Kenji Suzuki, Azumino-shi (JP)

(72) Inventor: Kenji Suzuki, Azumino-shi (JP)

(73) Assignee: FUJI ELECTRIC CO., LTD, Kawasaki-shi, (JP)

(21) Appl. No.: 13/978,300

(22) PCT Filed: Sep. 13, 2011
(86) PCT No.: PCT/JP2011/070777

§ 371 Date: Jul. 25, 2013

(30) Foreign Application Priority Data
Jan. 7, 2011 (JP) 2011-002356

(51) Int. Cl. H01L 23/367; H01L 23/00

(52) U.S. Cl. CPC H01L 23/367; H01L 24/80
USPC 361/717; 228/179.1

(57) ABSTRACT

A semiconductor device has, at least, a cooling base and a plurality of insulating substrates with conductive patterns fixed onto the cooling base through a solder. A solder pool portion is provided on the cooling base to contact a position of the cooling base directly below an edge of each of the insulating substrates with conductive patterns with a shortest distance from a center point of the cooling base.

### TECHNICAL FIELD

This invention relates to a semiconductor device such as a power semiconductor module, and to a manufacturing method for such a device.

### BACKGROUND ART

FIG. 15 is a cross-sectional view of principal portions of a conventional power semiconductor module. The power semiconductor module 500 comprises a cooling base 51, an insulating substrate with a conductive pattern 56, the rear face conductive film 53 of which is fixed onto the cooling base 51 via solder 52, and a semiconductor chip 58 fixed onto the top-side conductive pattern 55 via solder 57. Here reference numeral 54 is an insulating plate, forming the insulating substrate with a conductive pattern 56.

Also, the module is constituted by a resin case 61 fixed to the outer periphery of the cooling base 51; an outer conductive terminal 60 which penetrates the resin case 61; bonding wires 59 which connect the outer conductive terminal 60 and semiconductor chip 58 to the conductive pattern 55 and the like; a lid 62 which covers the resin case 61; and a gel 63 which fills the interior of the resin case 61.

In this structure, electrical insulation between the semiconductor chip 58 and the cooling base 51 is secured by the insulating plate 54 of the insulating substrate with a conductive pattern 56, and heat generated by the semiconductor chip 58 is dissipated via the cooling base 51 to a cooling fan, not shown.

In this way, heat generated by the semiconductor chip 58 passes through the insulating substrate with a conductive pattern 56 and cooling base 51 and is dissipated by the cooling fan, to prevent degradation and breakdown of the semiconductor chip 58.

Further, in the soldering method of Patent Document 1, a ceramic substrate is placed on a dissipating plate 2 on which protrusions are formed, a jig is mounted and the assembly is placed in a heating furnace in a mixture of nitrogen and hydrogen gases, and the dissipating plate is heated. Then, a pipe is inserted into a hole in the jig, and while using a pressing rod to press on the center portion of the ceramic substrate, solder is inserted into the pipe. After the molten solder has been made to enter the space between the ceramic substrate and the dissipating plate, it is cooled and solidified. By this means, it is stated that the rate of occurrence of voids in the solder between a ceramic insulating substrate of large area, on which a semiconductor chip is mounted, and the dissipating is reduced.

Further, Patent Document 2 discloses a module in which a substrate and a semiconductor element are joined by soldering. Here, the solder layer is shaped to be constituted by a main portion with the same shape as the planar shape of the semiconductor element, and an outflow portion which partially flows out therefrom. Because the solder layer does not flow out in all directions, there is no problem with positioning during placement. When the solder layer is melted due to rising temperature, air bubbles occur therein. The air bubbles move to the outflow portions from which they can escape relatively easily and escape to the outside. At this time, solder is replenished from the outflow portion to the paths in which air bubbles have traversed. Solder replenishment from the outflow portion is also implemented in a case of shrinkage of the solder layer upon cooling. Consequently, it is stated that no gaps remain between the substrate and the semiconductor element.

Patent Document 1: Japanese Patent Publication Application Laid-open No. H9-51049

Patent Document 2: Japanese Patent Publication Application Laid-open No. 2006-108522

FIG. 16 is a cross-sectional view of principal portions when an insulating substrate with a conductive pattern is fixed to a cooling base via solder. When fixing the insulating substrate with a conductive pattern 56 to the cooling base 51 via solder 52, for example a sheet of solder is placed on the cooling base 51 and the insulating substrate with a conductive pattern 56 is placed thereupon. Next, the sheet of solder is melted, the cooling base 51 is cooled, the molten solder is solidified, and the insulating substrate with a conductive pattern 56 is soldered to the cooling base 51. In this soldering process, the entirety of the cooling base 51 is not cooled to the same temperature, and there occur places in which the temperature decline is slow. Hence solidification proceeds in sequence from places where the temperature decline in the solder 52 below the insulating substrate with a conductive pattern 56 is fast.

Further, when molten solder changes to solidified solder, the volume decreases. Consequently, when the molten solder, the temperature decline of which is fast, solidifies, molten solder with a slower temperature decline is drawn in by the amount of the decrease in volume.

Consequently, because there is no more molten solder for solidifying molten solder to draw in, solder voids and solder cavities 64 and similar solder defects are formed in which solder is deficient.

When such solder cavities 64 occur, cracks are introduced from such places due to heat cycles and other thermal stresses, and reliability is reduced. Further, when there are solder voids, thermal resistance is increased.

This decrease in volume is more prominent for higher solidification shrinkage rates of the solder, and is larger for larger volumes of the solder (sheet solder or similar) prior to solidification.

Further, in Patent Documents 1 and 2, it is not stated that a solder pool portion is provided in the cooling base below each edge of the insulating substrate with a conductive pattern at the shortest distance from the center point of the cooling base. Moreover, there is no description or suggestion of a manufacturing method in which a solder pool portion is provided and moreover a temperature gradient is formed to the cooling base.

### DISCLOSURE OF THE INVENTION

An object of this invention is to provide a semiconductor device and a method of manufacturing such a device which can prevent the occurrence of solder defects such as solder cavities and solder voids.

In order to attain the above object, according to a first aspect of the invention, a semiconductor device has at least a cooling base and a plurality of insulating substrates with conductive patterns fixed onto the cooling base through solder. A solder pool portion is provided on the cooling base to contact a position of the cooling base directly below an edge of each of the insulating substrates with conductive patterns with a shortest distance from a center point of the cooling base.

Further, according to a second aspect of the invention, in the first aspect of the invention, it is preferable that a depression be provided in a bottom portion of the solder pool portion.

The position of the cooling base directly below each of the edges of the insulating substrates with conductive patterns which are at the shortest distance from the center point of the cooling base may be made at the places where the temperature decline of molten solder below each of the insulating substrates with conductive patterns is slowest.

Further, according to a third aspect of the invention, a method of manufacturing a semiconductor device having at least a cooling base and a plurality of insulating substrates with conductive patterns fixed onto the cooling base through solder is provided. This method includes a step of providing a solder pool portion on the cooling base to contact with places below the insulating substrates with conductive patterns where the molten solder solidifies most slowly.

Further, according to a fourth aspect of the invention, a method of manufacturing a semiconductor device having at least a cooling base and a plurality of insulating substrates with conductive patterns fixed onto the cooling base through a solder is provided. This method includes: a step of placing the plurality of insulating substrates with conductive patterns on the cooling base through a first molten solder and placing a second molten solder in a solder pool portion to contact the first molten solder; and a step of placing a ring-shaped cooling plate on a cooler contacting with an outer peripheral portion of the cooling base, placing the cooling base on the cooling plate, dissipating the heat of the cooling base to the cooler through the cooling plate, forming a temperature gradient to the cooling base such that a temperature of the outer peripheral portion of the cooling base is low and a temperature of a center point thereof is high, and sequentially solidifying the first molten solder while supplying the second molten solder from the solder pool portion to the first molten solder below the insulating substrates with conductive patterns.

Further, according to a fifth aspect of the invention, a method of manufacturing a semiconductor device having at least a cooling base and a plurality of insulating substrates with conductive patterns fixed onto the cooling base through a solder is provided. This method includes a step of positioning and placing a positioning jig on the cooling base; a step of inserting a first sheet solder into a first penetrating hole formed in the positioning jig, inserting a second sheet solder into a second penetrating hole contacting with the first penetrating hole, and inserting an insulating substrate with a conductive pattern onto the first sheet solder; a step of melting the first sheet solder and second sheet solder on the cooling base, to form a first molten solder and a second molten solder contacting with the first molten solder; and a step of placing a ring-shape cooling plate on a cooler contacting with an outer peripheral portion of the cooling base, placing the cooling base on the cooling plate, to slow a temperature decline at a center point of the cooling base than a temperature decline at an outer peripheral portion thereof, and solidifying the first molten solder while supplying the second molten solder from a solder pool portion to the first molten solder. The solder pool portion is provided on the cooling base to contact with a position of the cooling base at which a distance between an edge of each of the insulating substrates with conductive patterns and the center point thereof is shortest, and the second molten solder of the solder pool portion is made to solidify more slowly than the first molten solder.

Further, according to a sixth aspect of the invention, a method of manufacturing a semiconductor device having at least a cooling base and a plurality of insulating substrates with conductive patterns fixed onto the cooling base via solder is provided. This method includes: a step of placing the plurality of insulating substrates with conductive patterns on the cooling base through a first molten solder and providing a second molten solder in a solder pool portion contacting with the first molten solder; and a step of, by blowing low-temperature gas onto an outer peripheral portion of the cooling base, dissipating heat of the cooling base, forming a temperature gradient to the cooling base such that a temperature of an outer peripheral portion of the cooling base is low and a temperature at a center point thereof is high, and, while supplying the second molten solder from the solder pool portion to the first molten solder below the insulating substrates with conductive patterns, sequentially solidifying the first molten solder.

Further, according to a seventh aspect of the invention, in the invention described in any one of the third through sixth aspects, a manufacturing method may be used in which a depression is provided in the lower portion of the solder pool portion.

Further, according to an eighth aspect of the invention, in the sixth aspect, the gas may be hydrogen gas.

By means of this invention, in a semiconductor device in which an insulating substrate with a conductive pattern is fixed to a cooling base using a solder, when the solder below the insulating substrate with a conductive pattern is cooled and solidifies, a ring-shape cooling plate is placed below the cooling base to intentionally form a temperature gradient such that the temperature at the center point of the cooling base is higher than at the outer peripheral portion. By this means, a portion is intentionally created at which solidification of molten solder below each insulating substrate with a conductive pattern is slowest, and by providing a solder pool portion at this place, the occurrence of solder cavities, solder voids, and other solder defects can be prevented.

The above and other objects of the invention, as well as features and advantages will become clear through the attached drawings representing preferred embodiments as examples of the invention, and through the following related explanations.

### BRIEF DESCRIPTION OF THE DRAWINGS

FIGS. 1(a), 1(b) show the configuration of the semiconductor device of the first embodiment of the invention, wherein FIG. 1(a) is a plan view of principal portions and FIG. 1(b) is a cross-sectional view of principal portions along line X-X in FIG. 1(a).

FIG. 2 is a cross-sectional view of a manufacturing process of principal portions of the semiconductor device of the second embodiment of the invention.

FIG. 3 is a cross-sectional view of a manufacturing process, following FIG. 2, of principal portions of the semiconductor device of the second embodiment of the invention.

FIG. 4 is a cross-sectional view of a manufacturing process, following FIG. 3, of principal portions of the semiconductor device of the second embodiment of the invention.

FIG. 5 is a cross-sectional view of a manufacturing process, following FIG. 4, of principal portions of the semiconductor device of the second embodiment of the invention.

FIG. 6 is a cross-sectional view of a manufacturing process, following FIG. 5, of principal portions of the semiconductor device of the second embodiment of the invention.

FIGS. 7(a), 7(b) show the configuration of a cooling base used in the invention, wherein FIG. 7(a) is a plan view of principal portions and FIG. 7(b) is a cross-sectional view of principal portions along line X-X in FIG. 7(a).

FIGS. 8(a), 8(b) show the configuration of a positioning jig used in the invention, wherein FIG. 8(a) is a plan view of principal portions and FIG. 8(b) is a cross-sectional view of principal portions along line X-X in FIG. 8(a).

FIGS. 9(a), 9(b) show the configuration of a cooling plate used during cooling, wherein FIG. 9(a) is a plan view of principal portions and FIG. 9(b) is a cross-sectional view of principal portions along line X-X in FIG. 9(a).

FIG. 10 shows a state in which molten solder 6b has changed to the solidified solder 6.

FIGS. 11(a), 11(b) show the configuration of the semiconductor device of the third embodiment of the invention, wherein FIG. 11(a) is a plan view of principal portions and FIG. 11(b) is a cross-sectional view of principal portions along line X-X in FIG. 11(a).

FIG. 12 is a cross-sectional view of a manufacturing process of principal portions showing a method of manufacturing a semiconductor device of a fourth embodiment of the invention.

FIGS. 13(a), 13(b) show the configuration of a semiconductor device when there are two insulating substrates with conductive patterns 12 in the invention, wherein FIG. 13(a) is a plan view of principal portions and FIG. 13(b) is a cross-sectional view of principal portions along line X-X in FIG. 13(a).

FIG. 14 is a plan view of principal portions in a case where numerous insulating substrates with conductive patterns 12 are disposed on a cooling base 1.

FIG. 15 is a cross-sectional view of principal portions of a conventional power semiconductor module.

FIG. 16 is a cross-sectional view of principal portions when an insulating substrate with a conductive pattern is fixed to a cooling base via solder.

### BEST MODE FOR CARRYING OUT THE INVENTION

The aspects are explained using the following embodiments.

### First Embodiment

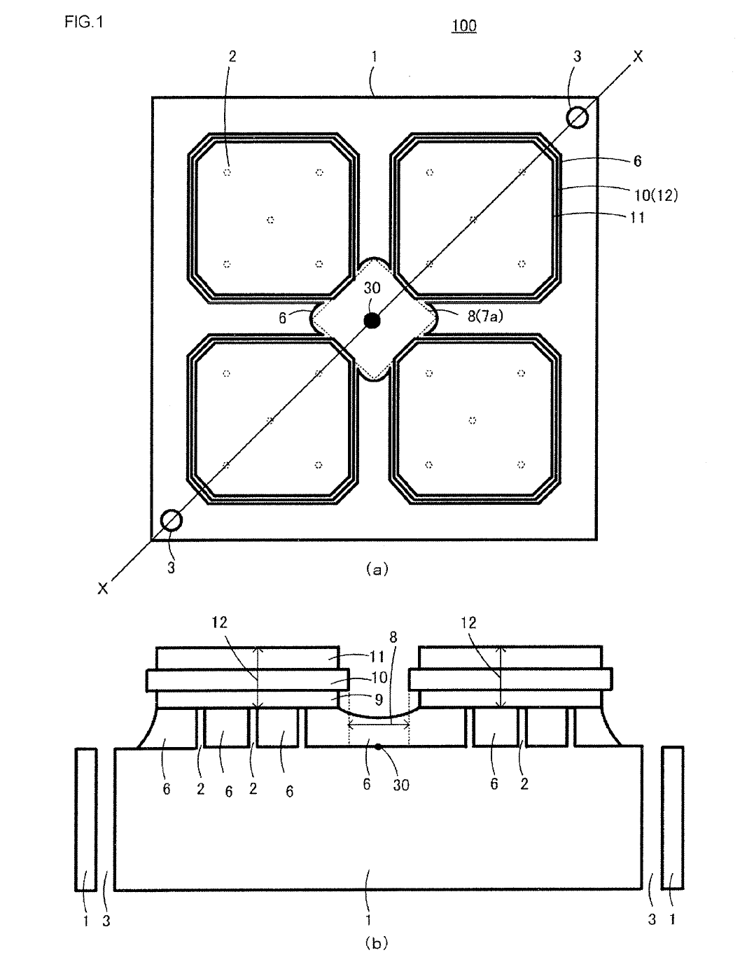

FIGS. 1(a), 1(b) show the configuration of the semiconductor device of the first embodiment of the invention, wherein FIG. 1(a) is a plan view of principal portions and FIG. 1(b) is a cross-sectional view of principal portions along line X-X in FIG. 1(a). Using this semiconductor device as an example of a power semiconductor module, the figure shows a state in which an insulating substrate with a conductive pattern is soldered onto a cooling base.

This semiconductor device 100 comprises at least the cooling base 1 and an insulating substrate with a conductive pattern 12, the rear-face conductive film 9 of which is fixed onto the cooling base 1 via solder 6, and moreover comprises a semiconductor chip, not shown, fastened to the top-side conductive pattern 11 via solder.

Further, this device is constituted by positioning and mounting holes 3 formed in the cooling base 1, a solder pool portion 8 which supplies molten solder to the molten solder below the insulating substrate with a conductive pattern 12, bonding wires or a lead frame fixed to the top electrodes of the semiconductor chip via solder, a resin case, not shown, fixed to the outer periphery of the cooling base 1, a lid, not shown, which covers the resin case, and a gel, not shown, which fills the interior of the resin case.

The solder pool portion 8 is a region surrounded by corners of four insulating plates 10, and is a place into which the sheet of solder 7a is set. This is a place in which, when molten solder solidifies, solidification is slowest, and is the center point of the cooling base 1.

The solder 6 in the above-described solder pool portion 8 is connected and integrated with the solder 6 below the insulating substrates with conductive patterns 12. The above-described insulating substrates with conductive patterns 12 each comprise an insulating plate 10, a rear-face conductive film 9 formed on the rear side of the insulating plate 10, and a conductive pattern 11 formed on the top side of the insulating plate 10. Reference numeral 2 in the figure denotes a height adjustment protrusion which adjusts the height of the molten solder 6b.

### Second Embodiment

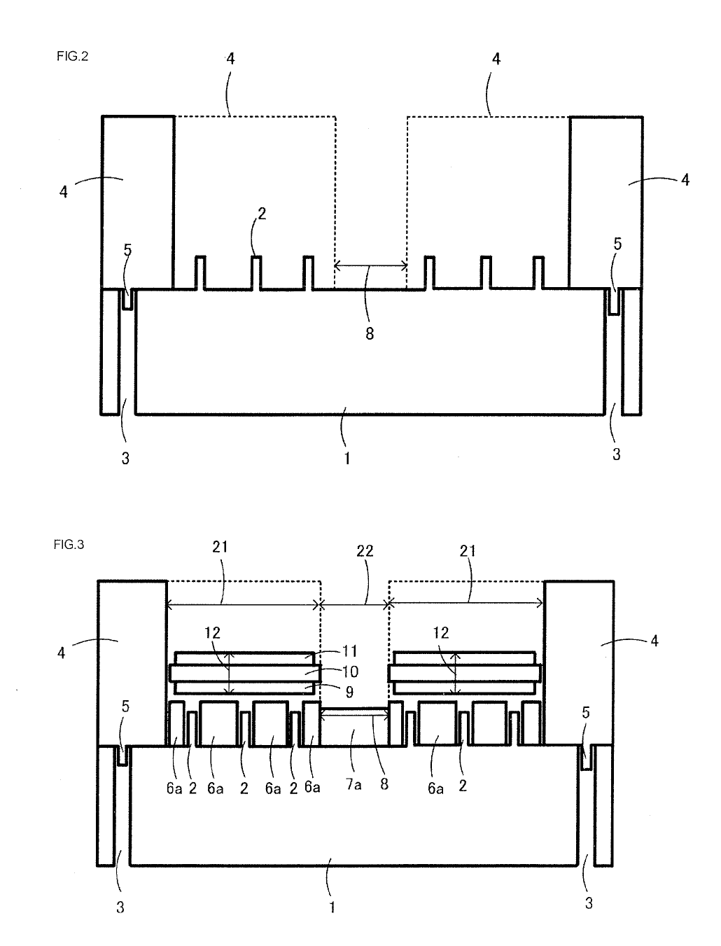

FIG. 2 to FIG. 6 are cross-sectional views of principal portions of manufacturing processes, showing consecutively processes of a manufacturing method for a semiconductor device in the second embodiment of the invention. These figures show manufacturing processes in a case in which insulating substrates with conductive patterns are fixed to a cooling base via solder.

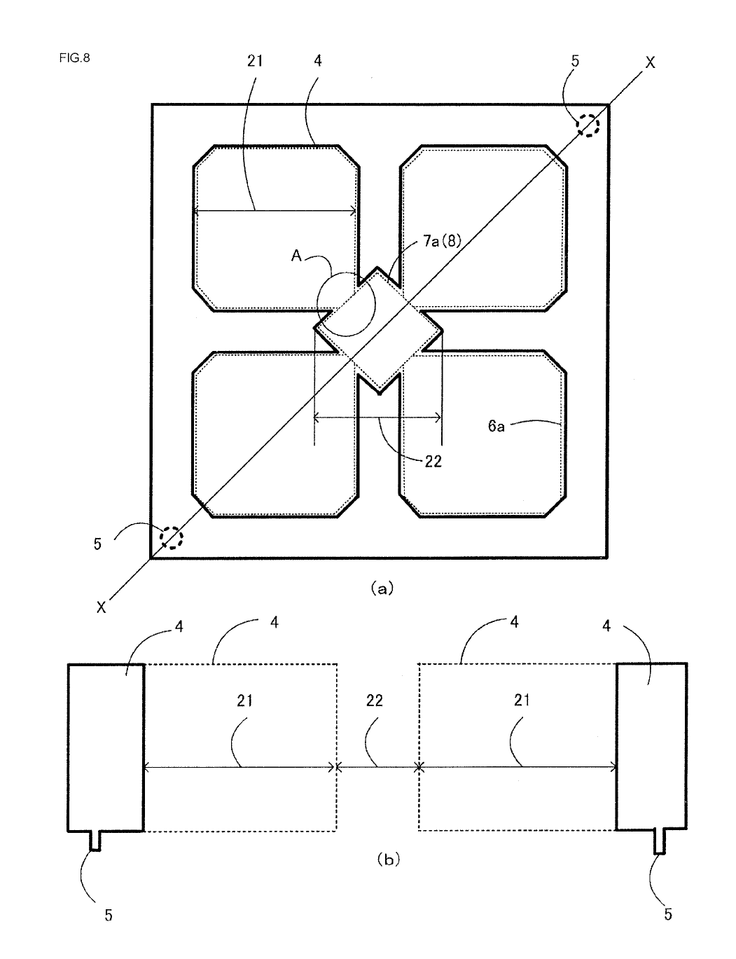

First, in FIG. 2, for example positioning pins 5 (for example pins formed integrally with the positioning jig 4 or metal pins which mate with the positioning jig 4) formed in the positioning jig 4 formed from carbon are inserted into the positioning and mounting holes 3 formed in the cooling base 1, and the positioning jig 4 is positioned and placed on the cooling base 1. As shown in FIG. 8 described below, first penetrating holes 21 which position the insulating substrates with conductive patterns 12 and a second penetrating hole 22 which positions the solder pool portion 8 are opened in the positioning jig 4. The first penetrating holes 21 and second penetrating hole 22 are in contact with corners as indicated by the portions A in FIG. 8.

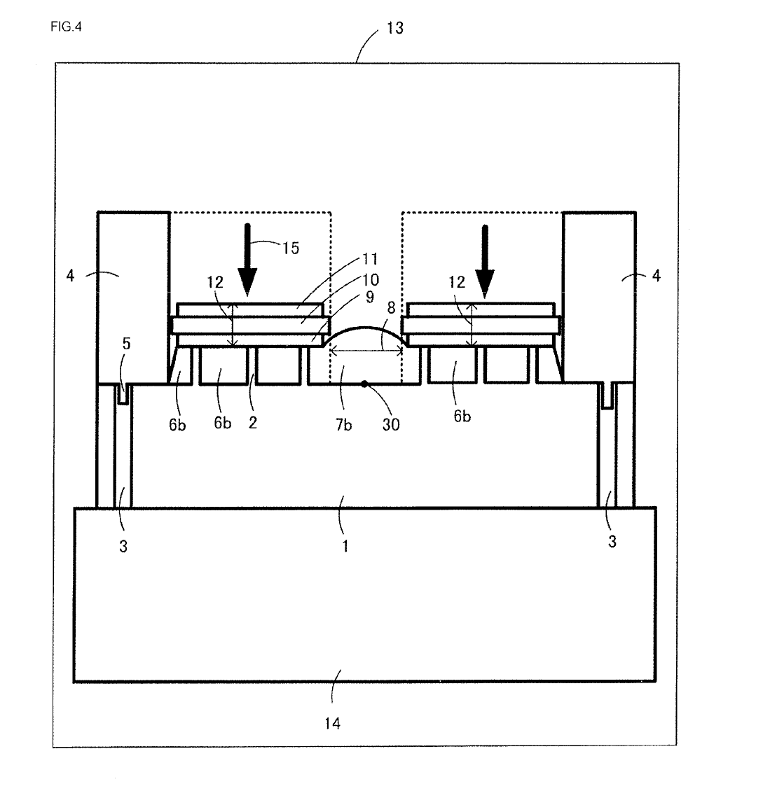

Next, in FIG. 3, sheets of solder 6a and 7a are respectively set as first sheets of solder and a second sheet of solder at the first penetrating holes 21 and second penetrating hole 22, and the insulating substrates with conductive patterns 12 are placed on the sheets of solder 6a set in the first penetrating holes 21. The quantity of the sheet of solder 7a set in the second penetrating hole 22 at this time is adjusted to an amount appropriate so that the molten solder 7b replenishes solder cavities below the insulating substrates with conductive patterns 12. The adjustment may conveniently be performed by adjusting the thickness of the sheets of solder 7a, for example.

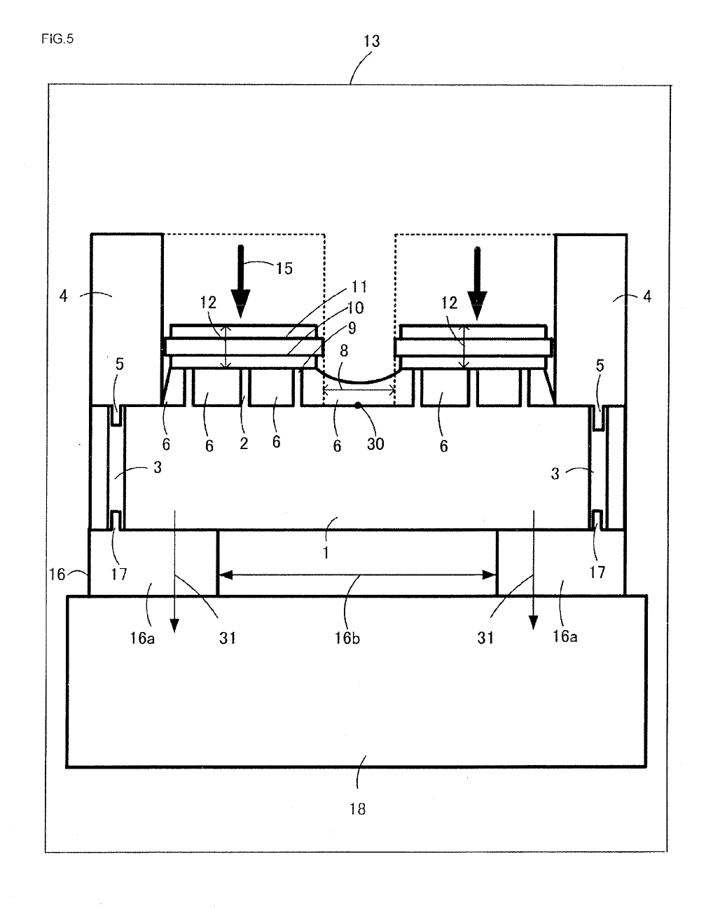

Next, in FIG. 4, the cooling base 1 is placed on a heater 14 in a chamber 13. While applying pressure 15 to the insulating substrates with conductive patterns 12 in the chamber 13 in a reducing environment, the sheets of solder 6a are melted to become molten solder 6b as the first molten solder. At this time the sheet of solder 7a also becomes the molten solder 7b as the second molten solder. Then, decompression is performed to eliminate bubbles. Because pressure 15 is being applied to the insulating substrates with conductive patterns 12, the rear-face conductive films 9 of the insulating substrates with conductive patterns 12 are in contact with height adjustment protrusions 2 formed on the cooling base 1 to adjust the height of the molten solder 6b, and the height of the molten solder 6b (the gap between the rear-face conductive films 9 of the insulating substrates with conductive patterns 12 and the face of the cooling base 1) is constant.

Next, in FIG. 5 a ring-shape cooling plate 16 is placed on the cooler 18 within the chamber 13. Protrusions 17 formed in the cooling plate 16 are inserted into the positioning and mounting holes 3 in the cooling base 1, and the assembly, with the ring-shape (frame shape) cooling plate 16 positioned and placed on the cooling base 1, is cooled by the cooler 18. The ring-shape plate portion 16a forms the periphery of this cooling plate 16, with a hole 16b (penetrating hole) opened in the center portion. Consequently the heat 31 of the cooling base is radiated to the cooler 18 via the ring-shape plate portion 16a of the cooling plate 16, so that the outer peripheral portion of the cooling base 1 cools rapidly, and the temperature decline of the center portion is slow. That is, by sandwiching this cooling plate 16, a temperature gradient is formed to the cooling base 1 such that the temperature is higher in the center portion (center point 30) and is lower on the periphery.

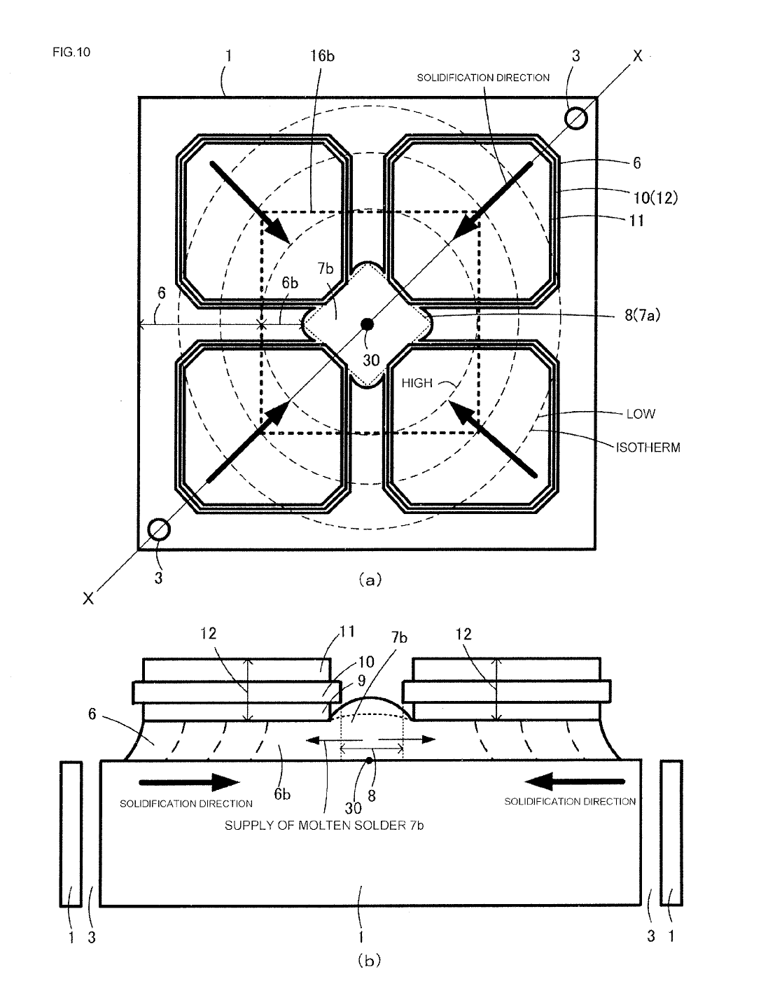

FIGS. 10(a), 10(b) show a state in which molten solder 6b changes into solidified solder 6. The temperature of the cooling base 1 declines from the outer peripheral portion, and the temperature decline is slowest at the center point 30. The molten solder 6b solidifies in the directions of the arrows. When the molten solder 6b changes into solidified solder 6, the volume shrinks. At this time the molten solder 7b near the center point 30 is in the melted state, and so molten solder 7b is supplied from the solder pool portion 8 so as to supplement this volume shrinkage. Consequently there is no occurrence of solder cavities at places in the corners of the insulating substrates with conductive patterns 12, as in the conventional devices.

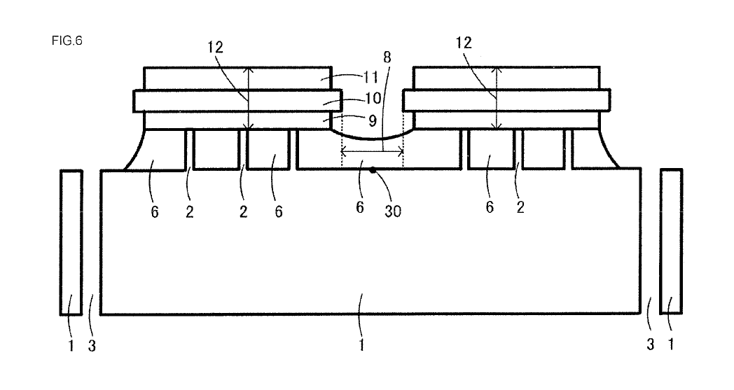

Next, in FIG. 6, the cooling base 1 is removed from the chamber 13 when the temperature of the cooling base 1 has fallen sufficiently, the positioning jig 4 is removed, and the insulating substrates with conductive patterns 12 fixed to the cooling base 1 with solder are completed.

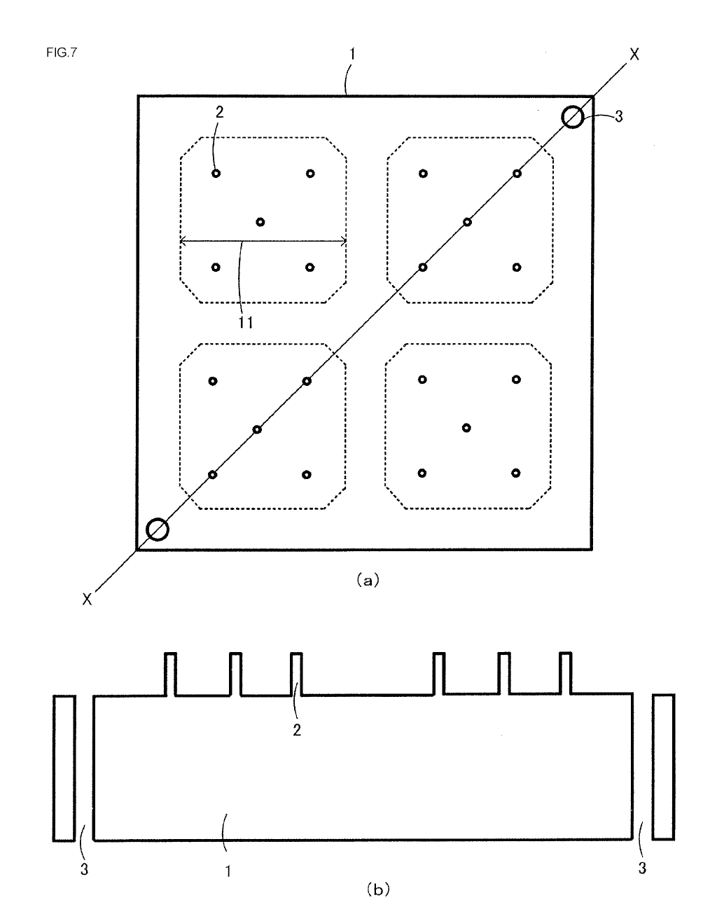

FIGS. 7(a), 7(b) show the configuration of a cooling base used in the invention, wherein FIG. 7(a) is a plan view of principal portions and FIG. 7(b) is a cross-sectional view of principal portions along line X-X in FIG. 7(a). Four insulating substrates with conductive patterns, indicated by the dotted lines, can be placed on this cooling base.

In the cooling base 1 are formed positioning and mounting holes 3, for insertion of positioning pins 5 formed in the positioning jig 4. In order that the height of the molten solder 6a is constant, height adjustment protrusions 2 are formed in a plurality of places. Here, protrusions are formed in five places, but no particular limitations are imposed so long as the insulating substrates with conductive patterns can be supported.

FIGS. 8(a), 8(b) show the configuration of a positioning jig used in the invention, wherein FIG. 8(a) is a plan view of principal portions and FIG. 8(b) is a cross-sectional view of principal portions along line X-X in FIG. 8(a).

Positioning pins 5 are formed in the positioning jig 4, and first penetrating holes 21 for positioning are formed to position the sheets of solder 6a and insulating substrates with conductive patterns 12. Further, a second penetrating hole 22 is disposed in the center at the place which becomes the solder pool portion 8. The place of this second penetrating hole 22 is the place corresponding to the places at which the temperature decline is slower than at other places on the cooling base 1. Further, the sheet of solder 7a disposed in this solder pool portion 8 is disposed so as to be in contact, at the portions A, with the sheets of solder 6a disposed below the insulating substrates with conductive patterns 12.

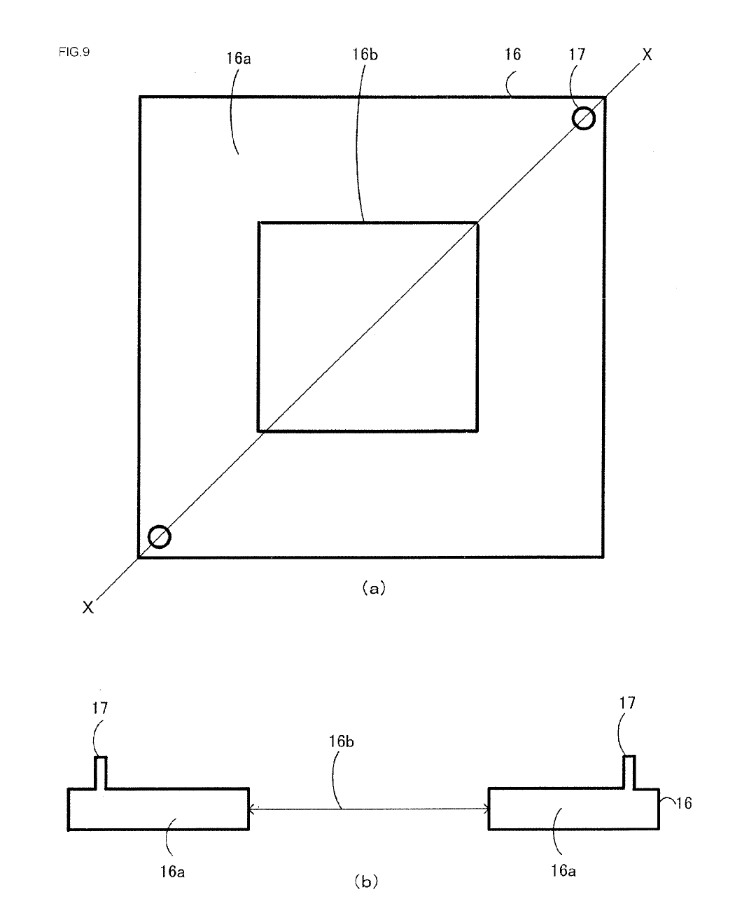

FIGS. 9(a), 9(b) show the configuration of a cooling plate used during cooling, wherein FIG. 9(a) is a plan view of principal portions and FIG. 9(b) is a cross-sectional view of principal portions along line X-X in FIG. 9(a).

This cooling plate 16 has a hole 16b opened in the center portion, and is positioned such that the center point 30 of the hole 16b coincides with the center point of the solder pool portion 8. Heat from the cooling base 1 is radiated to the cooler 18 via the ring-shape plate portion 16a, so that the temperature decline in the vicinity of the cooling base 1 is fast, and the temperature decline in the solder pool portion 8 is slower than in other places. As a result, molten solder 7b is supplied from the solder pool portion 8 to corners of the insulating substrates with conductive patterns 12 adjacent to the solder pool portion 8, at which solder defects readily occur, solder deficiencies at the corners are alleviated, and the occurrence of solder cavities, solder voids, and other solder defects is prevented.

As a result, a semiconductor device can be provided with few solder defects, high resistance to heat cycles, high reliability, and low thermal resistance.

Instead of installing the cooling plate 16, a cool gas may be blown onto places contacting with the plate portion 16a of the cooling plate 16 to cool the vicinity of the cooling base 1.

### Third Embodiment

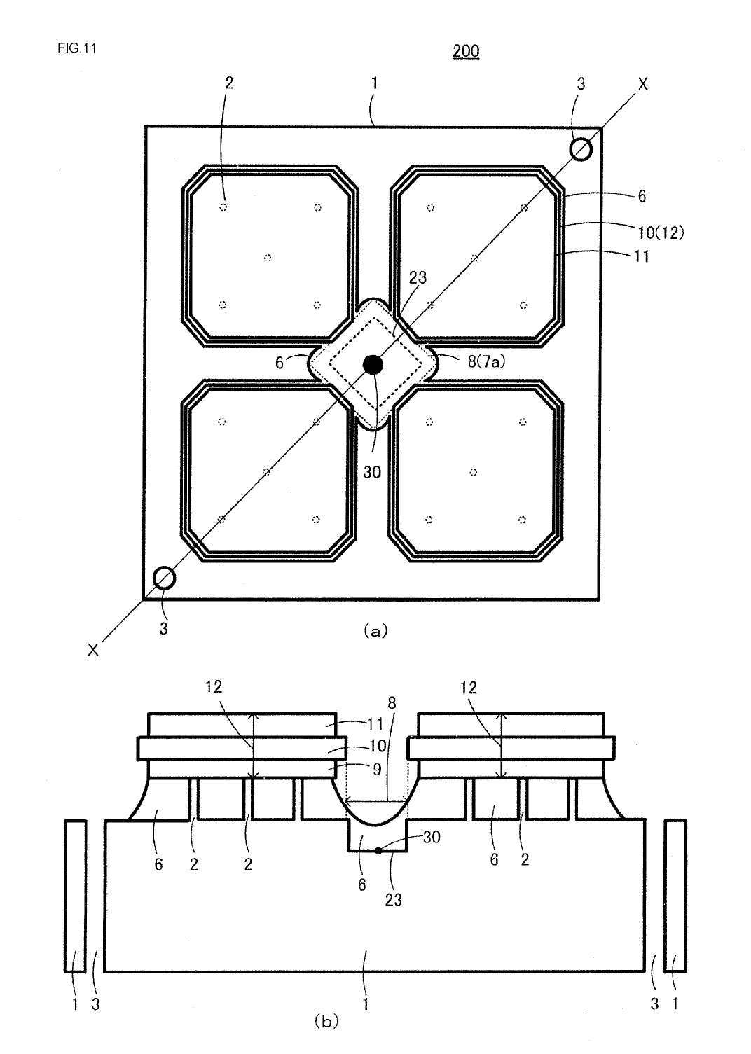

FIGS. 11(a), 11(b) show the configuration of the semiconductor device of a third embodiment of the invention, wherein FIG. 11(a) is a plan view of principal portions and FIG. 11(b) is a cross-sectional view of principal portions along line X-X in FIG. 11(a). This semiconductor device is an example of a power semiconductor module.

A difference between this semiconductor device 200 and the semiconductor device 100 of the first embodiment is the fact that a depression 23 is provided at the bottom of the solder pool portion 8. By providing the depression 23, the solder fillet is improved, and heat cycle resistance is further improved.

### Fourth Embodiment

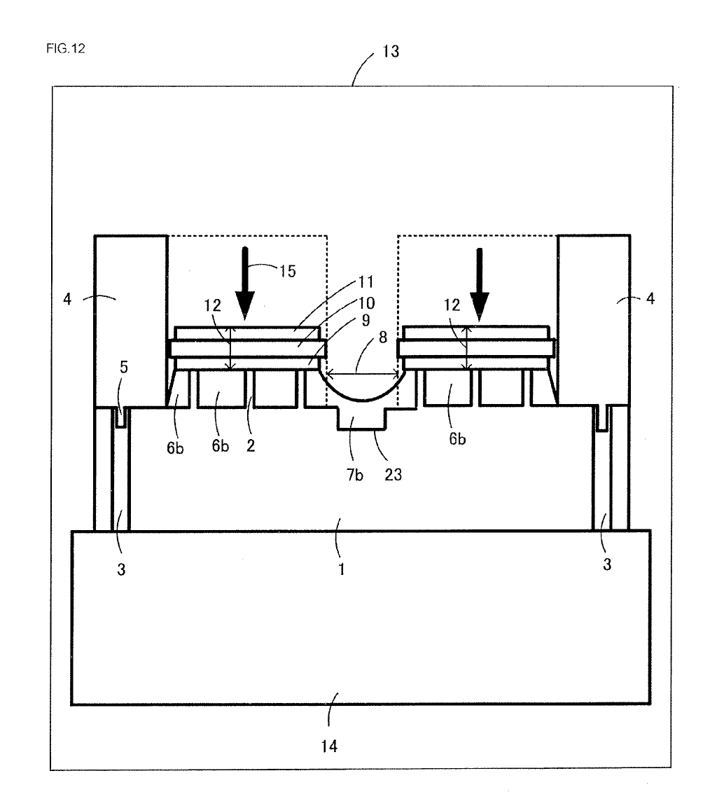

FIG. 12 is a cross-sectional view of a manufacturing process of principal portions showing a method of manufacturing a semiconductor device of a fourth embodiment of the invention. A difference with the second embodiment is that, by providing a depression 23 in the bottom portion of the solder pool portion 8, molten solder 7b in the solder pool portion 8 flows into the depression 23, and the surface shape (solder fillet) of the solidified solder 6 is improved.

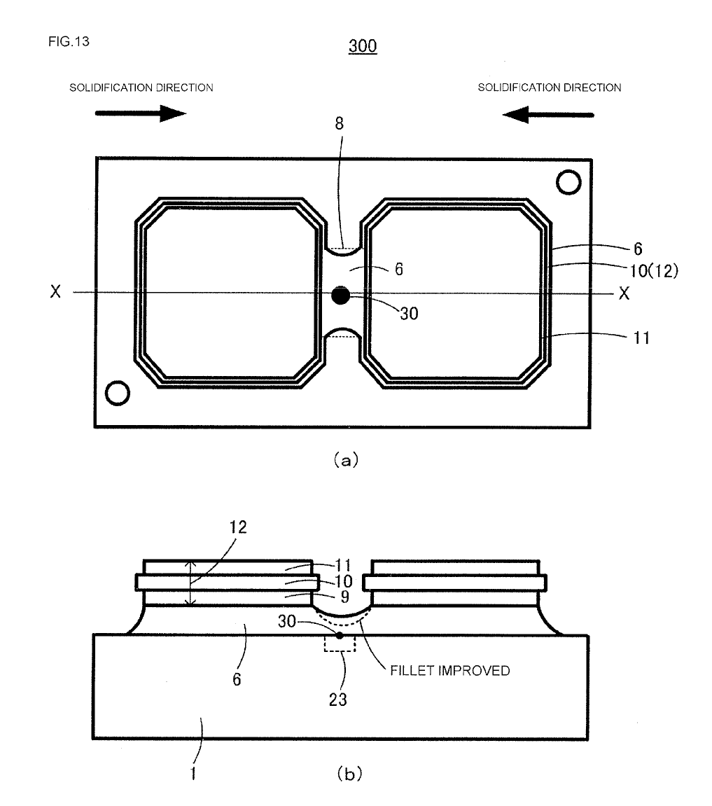

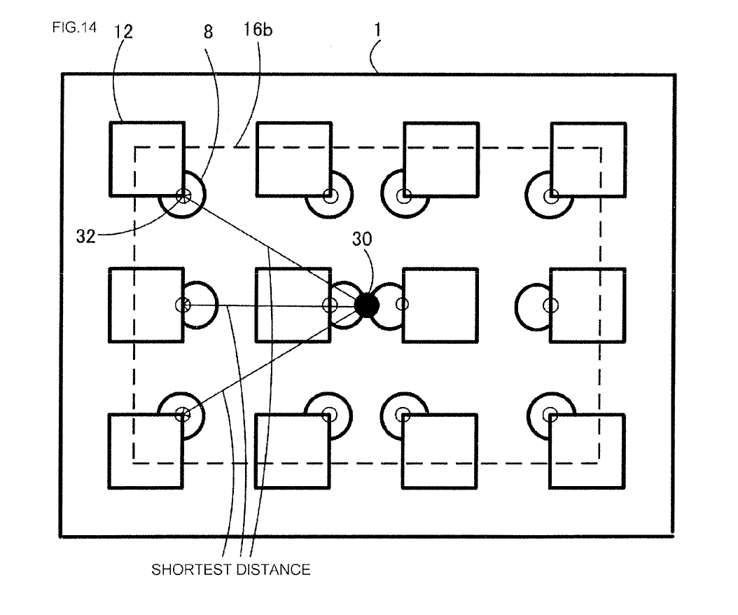

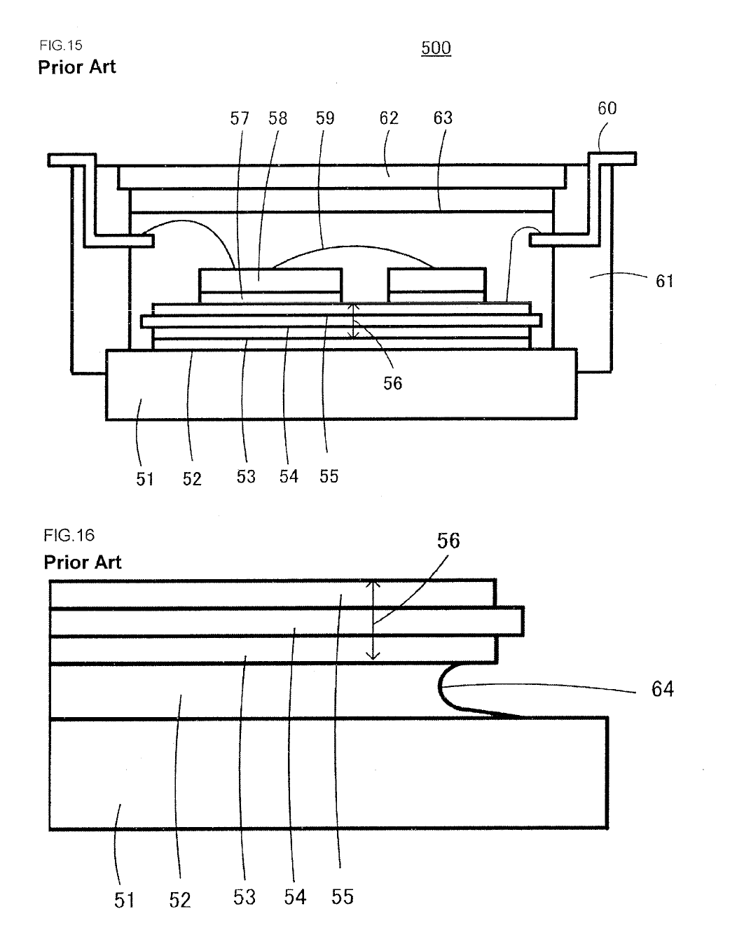

In the first to fourth embodiments, it was explained in which four insulating substrates with conductive patterns 12 are soldered to a cooling base 1; FIGS. 13(a), 13(b) show a semiconductor device 300 of the invention in a case where there are two insulating substrates with conductive patterns 12. In this case, the solder pool portion 8 may be disposed in the center portion of the insulating substrates with conductive patterns 12, with cooling performed from both sides so that solder is solidified in the directions indicated by the arrows. Further, if a depression 23 is provided in the center portion as indicated by a dashed line, the solder fillet is improved.

As shown in FIG. 14, when numerous insulating substrates with conductive patterns 12 are disposed on a cooling base 1, if solder pool portions 8 are provided at the position 32 of each of the insulating substrates with conductive patterns 12 the shortest distance from the place where the temperature decline on the cooling base 1 is slowest (for example, the center point 30 of the cooling base 1), similar advantageous results are obtained.

In the above, only the principles of the invention have been described. Numerous modifications and alterations can be made by a person skilled in the art, and the invention is not limited to the precise configurations and application examples described above. All corresponding modifications and equivalent inventions should be regarded as within the scope of the attached claims of the invention and inventions equivalent thereto.

### EXPLANATION OF REFERENCE NUMERALS

1: Cooling base
2: Height adjustment protrusion
3: Positioning and mounting hole
4: Positioning jig
5: Positioning pin
6: Solder (solidified solder)
6a: Sheet of solder (sheet of solder below insulating substrate with a conductive pattern)
6b: Molten solder (molten solder below insulating substrate with a conductive pattern)
7a: Sheet of solder (sheet of solder placed in solder pool portion 8)
7b: Molten solder (molten solder in solder pool portion 8)
8: Solder pool portion
9: Rear-face conductive film
10: Insulating plate
11: Conductive pattern
12: Insulating plate with a conductive pattern
13: Chamber
14: Heater
15: Pressure
16: Cooling plate
16a: Ring-shape plate portion
16b: Hole
17: Protrusion
18: Cooler
21: First penetrating hole
22: Second penetrating hole
23: Depression
30: Center point
31: Heat
32: Position

1. A semiconductor device, comprising:
at least, a cooling base and a plurality of insulating substrates with conductive patterns fixed onto the cooling base through a solder,
wherein a solder pool portion is provided on the cooling base to contact a position of the cooling base directly below an edge of each of the insulating substrates with conductive patterns, with a shortest distance from a center point of the cooling base.

2. A semiconductor device according to claim 1, wherein a depression is provided in a bottom portion of the solder pool portion.

3. A method of manufacturing a semiconductor device having at least, a cooling base and a plurality of insulating substrates with conductive patterns fixed onto the cooling base through a solder, comprising:
a step of providing a solder pool portion on the cooling base to contact with places below the insulating substrates with conductive patterns, where a molten solder solidifies most slowly.

4. A method of manufacturing a semiconductor device having at least, a cooling base and a plurality of insulating substrates with conductive patterns fixed onto the cooling base through a solder, comprising:
a step of placing the plurality of insulating substrates with conductive patterns on the cooling base through a first molten solder and placing a second molten solder in a solder pool portion to contact with the first molten solder; and
a step of placing a ring-shaped cooling plate contacting with an outer peripheral portion of the cooling base on a cooler, placing the cooling base on the cooling plate to dissipate heat of the cooling base to the cooler through the cooling plate, forming a temperature gradient to the cooling base so that a temperature of the outer peripheral portion of the cooling base is low and a temperature of a center point thereof is high, and sequentially solidifying the first molten solder while supplying the second molten solder from the solder pool portion to the first molten solder below the insulating substrates with conductive patterns.

5. A method of manufacturing a semiconductor device having at least, a cooling base and a plurality of insulating substrates with conductive patterns fixed onto the cooling base through a solder, comprising:
a step of positioning and placing a positioning jig on the cooling base;
a step of inserting a first sheet solder into a first penetrating hole formed in the positioning jig, inserting a second sheet solder into a second penetrating hole contacting with the first penetrating hole, and inserting the insulating substrate with a conductive pattern onto the first sheet solder;
a step of melting the first sheet solder and the second sheet solder on the cooling base, to form a first molten solder and a second molten solder contacting with the first molten solder; and
a step of placing a ring-shape cooling plate contacting with an outer peripheral portion of the cooling base on a cooler, placing the cooling base on the cooling plate, to slow a temperature decline at a center point of the cooling base than a temperature decline at an outer peripheral portion thereof, and solidifying the first molten solder while supplying the second molten solder from a solder pool portion to the first molten solder,
wherein the solder pool portion is disposed at a position on the cooling base with a shortest distance between an edge of each of the insulating substrates with conductive patterns and the center point thereof, to contact the cooling base, so that the second molten solder of the solder pool portion is made to solidify more slowly than the first molten solder.

6. A method of manufacturing a semiconductor device having at least, a cooling base and a plurality of insulating substrates with conductive patterns fixed onto the cooling base through a solder, comprising:
a step of placing the plurality of insulating substrates with conductive patterns on the cooling base through a first molten solder and providing a second molten solder in a solder pool portion contacting with the first molten solder; and
a step of, by blowing low-temperature gas onto an outer peripheral portion of the cooling base, dissipating heat of the cooling base, forming a temperature gradient to the cooling base so that a temperature of the outer peripheral portion of the cooling base is low and a temperature at a center point thereof is high, and while supplying the second molten solder from the solder pool portion to the first molten solder below the insulating substrates with conductive patterns, solidifying sequentially the first molten solder.

7. A method of manufacturing a semiconductor device according to claim 3, wherein a depression is provided in a lower portion of the solder pool portion.

8. A method of manufacturing a semiconductor device according to claim 6, wherein the gas is hydrogen gas.
